(19) United States
(12) Patent Application Publication
(10) Pub. No.: US 2013/0248840 A1
(43) Pub. Date: Sep. 26, 2013

(54) FLUORENE DIMERS AND TRIMERS

(71) Applicant: General Electric Company, Schenectady, NY (US)

(72) Inventors: James Anthony Cella, Clifton Park, NY (US); Joseph John Shiang, Niskayuna, NY (US)

(73) Assignee: General Electric Company, Schenectady, NY (US)

(21) Appl. No.: 13/897,653

(22) Filed: May 20, 2013

Related U.S. Application Data
(63) Continuation of application No. 12/493,781, filed on Jun. 29, 2009.

(51) Int. Cl. H01L 51/00; H01L 51/56

(52) U.S. Cl. CPC H01L 51/0039; H01L 51/56
USPC 257/40; 438/46

(57) ABSTRACT

Solution processes for fabricating an optoelectronic devices include contacting an electroluminescent layer comprising an alcohol-insoluble electroluminescent polymer with an alcoholic solution of a compound of formula Ia to form an electron transporting layer directly disposed on the electroluminescent layer; and depositing a metal cathode layer on the electron transporting layer;

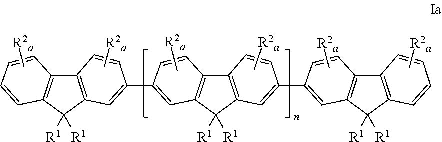

wherein
R¹ is, independently at each occurrence, C₁₋₂₀ hydrocarbyl;
at least one of R¹ is R³;
R² is independently at each occurrence hydrogen, C₁₋₂₀ hydrocarbyl, C₁₋₂₀ hydrocarbyloxy, C₁₋₂₀ thioether, C₁₋₂₀ hydrocarbylcarbonyloxy or cyano;
R³ is C₁₋₂₀ hydrocarbyl containing at least one S, N, O or P atom between carbon atoms;
a is independently at each occurrence 0, 1 or 2; and
n is 0 or 1.

### CROSS-REFERENCE TO RELATED APPLICATIONS

This application is a continuation of prior U.S. application Ser. No. 12/493,781, filed on Jun. 29, 2009, now co-pending, the entire disclosure of which is incorporated herein by reference.

### STATEMENT REGARDING FEDERALLY SPONSORED RESEARCH AND DEVELOPMENT

This invention was made with Government support under contract number DE-FC26-05NT42343 awarded by the U.S. Department of Energy. The Government has certain rights in the invention.

### BACKGROUND

In an OLED device, electrons and holes injected from the cathode and anode respectively combine in an emissive layer producing singlet and triplet excitons that can decay radiatively producing light or non-radiatively producing heat. For most organic molecules, light emission from the triplet state is a spin-forbidden process that does not compete well with non-radiative modes of decay, so triplet excitons are not very emissive. Transition metal complexes, by virtue of spin-orbit coupling, can radiatively decay with an efficiency that competes with non-radiative pathways. When these complexes are incorporated into OLED devices it is possible to achieve nearly 100% internal quantum efficiency since both singlet and triplet excitons produced in the device can emit light.

For solution processable OLED devices the transition metal complexes are typically incorporated into polymeric hosts by blending or via covalent attachment to the polymer host. Suitable polymeric hosts for these types of devices have triplet energies higher than the emissive guest transition metal complexes to ensure favorable energy transfer. Triplet excitons generated in the host polymer migrate until they encounter an emissive guest, when energy transfer excites the guest and light emission occurs. Triplet excitons from the host can also migrate toward the anode or cathode where they may be quenched in a non-radiative fashion. It is therefore desirable to confine the triplet excitons to maximize the probability of encounter with an emissive guest and prevent migration toward the electrodes, particularly the cathode. One way to prevent exciton migration toward the cathode is to insert a blocking layer having a triplet energy that is greater than that of the host emissive layer between the cathode and the emissive layer. The blocking layer may also promote electron injection from the cathode and have good electron mobility.

### BRIEF DESCRIPTION

Briefly, in one aspect, the present invention relates to optoelectronic devices, particularly OLEDs, that include triplet blocking compounds of formula I

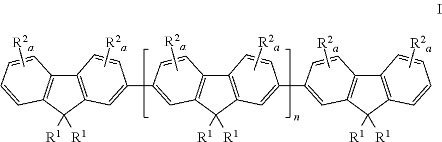

wherein
R¹ is, independently at each occurrence, C₁₋₂₀ hydrocarbyl and at least one of R¹ is R³;
R² is independently at each occurrence C₁₋₂₀ hydrocarbyl, C₁₋₂₀ hydrocarbyloxy, C₁₋₂₀ thioether, C₁₋₂₀ hydrocarbylcarbonyloxy or cyano;
R³ is —R⁴XR⁵;
R⁴ is a direct bond, C₁₋₂₀ aryl, C₁₋₂₀ arylalkyl, C₁₋₂₀ alkylaryl, C₁₋₂₀ substituted aryl, C₁₋₂₀ substituted arylalkyl, or C₁₋₂₀ substituted alkylaryl;
R⁵ is C₁₋₂₀ hydrocarbyl or C₁₋₂₀ hydrocarbyl containing at least one S, N, O or
P atom between carbon atoms;
R⁶ is C₁₋₂₀ alkyl or C₁₋₂₀ substituted alkyl;
X is —O—, —S—, —COO—, —OOC—, —CSS—, —SSC—, NR⁶ or PR⁶;
a is independently at each occurrence 0, 1 or 2; and
n is 0 or 1.

In another aspect, the present invention relates to compounds of formula Ia

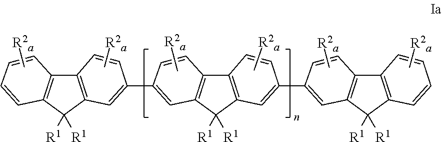

R¹ is, independently at each occurrence, C₁₋₂₀ hydrocarbyl and at least one of R¹ is R^{1a};
R² is independently at each occurrence C₁₋₂₀ hydrocarbyl, C₁₋₂₀ hydrocarbyloxy, C₁₋₂₀ thioether, C₁₋₂₀ hydrocarbylcarbonyloxy or cyano;
R^{3a} is C₁₋₂₀ hydrocarbyl containing at least one S, N, O or P atom between carbon atoms;
a is independently at each occurrence 0, 1 or 2; and
n is 0 or 1.

### DETAILED DESCRIPTION

The present invention relates to optoelectronic devices that include a series of layers: an anode, typically indium tin oxide (ITO), a hole injection layer to facilitate the injection of positive charge carriers from the ITO into the organic layers; one or more emissive layers in which electrons and holes recombine to emit light, an electron transporting and triplet blocking layer that includes compounds of formula I or Ia, and an electron injecting cathode.

Table 1 shows the ordering of energy levels as the total number of fluorene units in the oligomer is changed. Polymers comprised of oligomeric units also have comparable LUMO levels (thus promoting the injection of electrons into the emissive layer) and somewhat deeper HOMO levels, thus inhibiting holes from migrating from the emissive layer. Finally, these materials have solubility properties that enable the solution processed fabrication of a multilayer device.

TABLE 1
Spectroscopic data of reference 7 showing the measured evolution of triplet
energies with oligomer length.

| Number of fluorene units | Triplet Energy (eV) |
|---|---|
| 1 | 2.85 |
| 3 | 2.25 |
| 5 | 2.18 |
| 7 | 2.16 |
| polymer | 2.11 |

Thus, the compounds of formula I are well suited for use as triplet blocking layers in devices in which triplet level of the emissive layer is equal to or lower than that of polyfluorene (T1=2.11 eV).

In order to satisfy the requirement that these materials promote electron injection and mobility, the optoelectronic devices of the present invention include compounds that bear polar substituents in the 9-position of the fluorene segments. Accordingly, in one aspect, the present invention relates to compounds of formula I that may be used as triplet blocking materials in an optoelectronic device. The polar substituents include at least one S, N, O or P atom between carbon atoms, and may include up to about 10 S, N, O or P heteroatoms. The term “between carbon atoms” means that the heteroatom is not part of a terminal group such as hydroxyl, carbonyl, carboxyl, aldehydic (—CHO); groups that are between carbon atoms include, but are not limited to ether, thioether, ester, thioester, and amino groups. The heteroatoms may be all of one type, for example, all O atoms, or may be a mixture of some or all of S, N, O and P. In particular, the heteroatoms may be present as part of one or more ether, thioether, ester, thioester, or amino groups.

In particular embodiments, the compounds of formula I are of formula

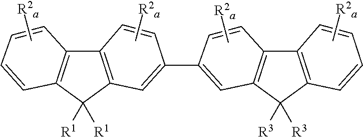

In other embodiments, the compounds of formula I are of formula

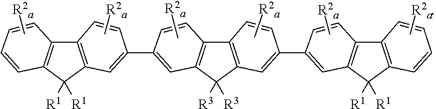

R¹ may be, independently at each occurrence, alkyl or R³.

More specifically, in the compounds of formula I, R³ may be

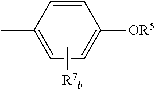

wherein
R⁷ is C₁₋₂₀ hydrocarbyl, C₁₋₂₀ hydrocarbyloxy, C₁₋₂₀ thioether, C₁₋₂₀ hydrocarbylcarbonyloxy or cyano; and
b is 0, 1 or 2.
   R⁵ may be morpholinyl or pyrrolidinyl, and particularly, R⁵ may be selected from

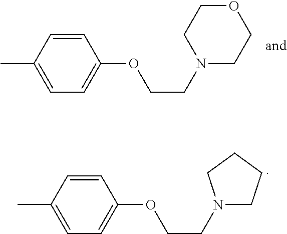 [SMILES: Cc1ccc(OCCN2CCOCC2)cc1 ; Cc1ccc(OCCN2CCCC2)cc1]

In specific embodiments, R³ may be —O(CH₂CH₂O)ₘCH₂CH₂NR⁶; and m is 0 or an integer from 0 to about 20, or R³ may be selected from

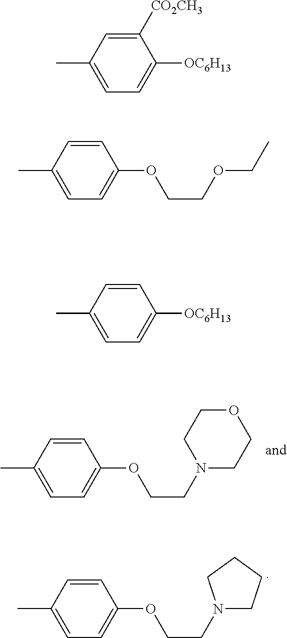

In exemplary compounds of the present invention,

—R¹ is C₈H₁₇ and R³ is selected from

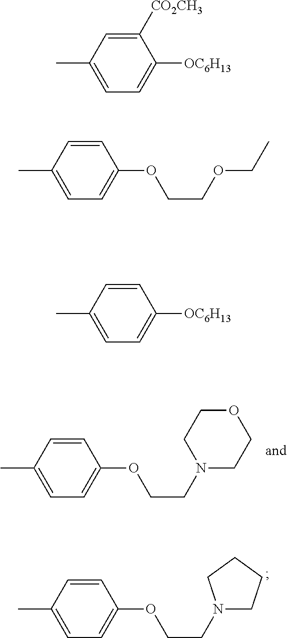

### —R¹ is

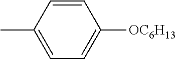

and

R³ is selected from

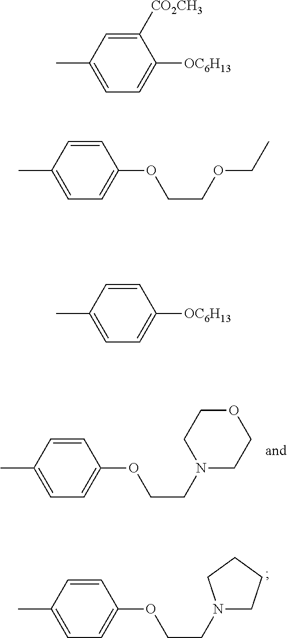

### —R¹ is C₈H₁₇ and R³ is

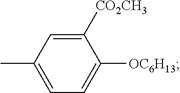

### —R¹ is C₈H₁₇ and R³ is

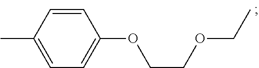

### —R¹ is C₈H₁₇ and R³ is

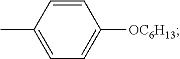

### —R¹ is C₈H₁₇ and R³ is

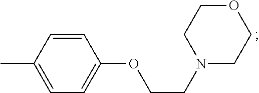 [SMILES: Cc1ccc(OCCN2CCOCC2)cc1]

—R¹ is

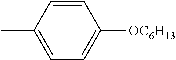

### and R³ is

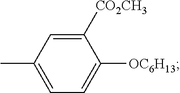

### —R¹ is

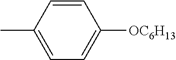

### and R³ is

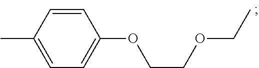

### —R¹ is

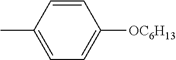

### and R³ is

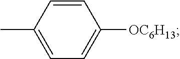

### —R¹ is

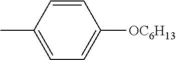

### and R³ is

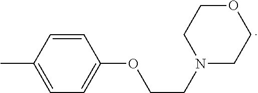 [SMILES: Cc1ccc(OCCN2CCOCC2)cc1]

In another aspect, the present invention relates to optoelectronic devices comprising

a cathode;
an anode;
an electroluminescent layer disposed between the cathode and the anode; and
a layer disposed between the electroluminescent layer and the cathode, and comprising a compound of formula Ia.
The genus encompassed by the compounds of formula Ia includes the compounds of formula I

In some embodiments, the compound of formula Ia is

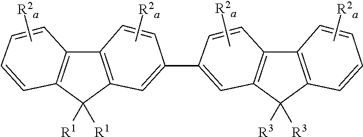

and in others, the compound of formula Ia is

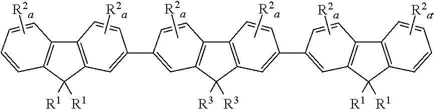

In yet other embodiments, the optoelectronic device includes compounds of formula 1a, wherein R^{3a} is C₁₋₂₀ hydrocarbyl containing at least one ether, thioether, ester, thioester, or alkylamino group.

Some examples of suitable oligomer blocking layers are presented in Table 2.

TABLE 2
Oligofluorene Triplet Blocking Materials

| # | R | R′ | R″ | Mw |
|---|---|---|---|---|
| 392-38 | C₈H₁₇ | C₈H₁₇ | 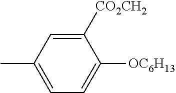 | 1408 |
| 392-57 | C₈H₁₇ | C₈H₁₇ | 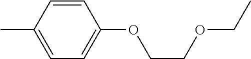 | 1270 |
| 392-59 | C₈H₁₇ | C₈H₁₇ | 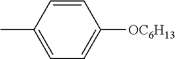 | 1294 |
| 392-65 | 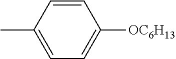 | 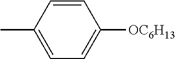 | 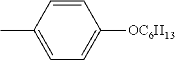 | 1550 |
| 392-74 | C₈H₁₇ | C₈H₁₇ | 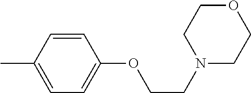 | 1352 |
| 392-83 | 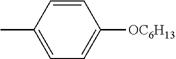 | 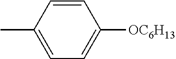 | 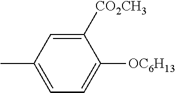 | 1664 |
| 392-84 | 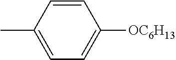 | 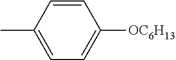 | 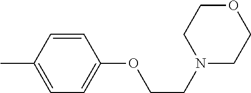 | 1608 |
| 392-85 | C₈H₁₇ | C₈H₁₇ | 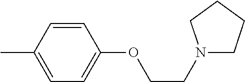 | 1320 |
| 392-89 | 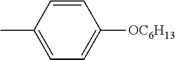 | 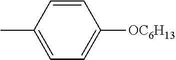 | 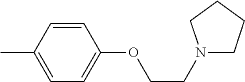 | 1576 |

The compounds of formula I are typically amorphous materials that can be cast into thin films by evaporative casting from a suitable organic solvent. As long as the fluorene oligomer length does not exceed about 3 fluorene segments, the triplet energies of these oligomers is higher than most emissive hosts materials and triplet blocking may occur.

The compounds of formula I may be readily prepared by typical aryl coupling reactions such as the Suzuki or Yamamoto coupling. In particular, the compounds may be prepared by Suzuki cross-coupling reactions. The general procedure for Suzuki cross-coupling reactions includes mixing an aryl halide and aryl borate (or boronic acid) in a suitable solvent, in the presence of a base and Pd catalyst, and heating under an inert atmosphere. Suitable solvents include, but are not limited, to dioxane, THF, ethanol, toluene and mixtures thereof. Exemplary bases include Na₂CO₃, K₂CO₃, Cs₂CO₃, potassium phosphate and hydrates thereof. The bases may be added to the reaction as a solid powder or as an aqueous solution. Suitable catalysts include Pd(PPh₃)₄, Pd(OAc)₂, and Pd(dba)₂ with the addition of a secondary ligand. Exemplary ligands include dialkylphosphinobiphenyl ligands shown below, in which Cy is cyclohexyl.

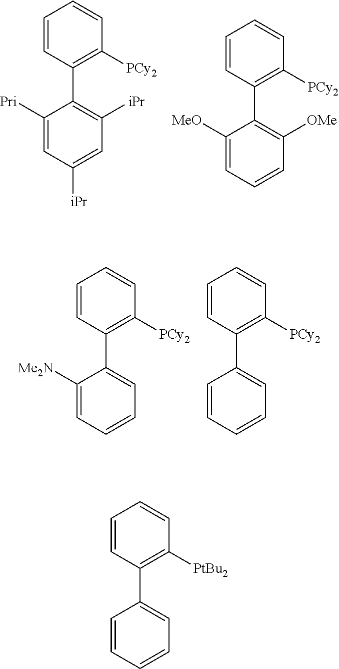

An optoelectronic device includes, in the simplest case, an anode layer and a corresponding cathode layer with an electroluminescent layer disposed between the anode and the cathode. When a voltage bias is applied across the electrodes, electrons are injected by the cathode into the electroluminescent layer while electrons are removed from (or “holes” are “injected” into) the electroluminescent layer from the anode. For an organic light emitting device (OLED), light emission occurs as holes combine with electrons within the electroluminescent layer to form singlet or triplet excitons, light emission occurring as singlet and/or triplet excitons decay to their ground states via radiative decay. For a photovoltaic (PV) device, light absorption results in an electric current flow.

Other components which may be present in an optoelectronic device in addition to the anode, cathode and light emitting material include a hole injection layer, an electron injection layer, and an electron transport layer. The electron transport layer need not be in direct contact with the cathode, and frequently the electron transport layer also serves as a hole blocking layer to prevent holes migrating toward the cathode. Additional components which may be present in an organic light-emitting device include hole transporting layers, hole transporting emission (emitting) layers and electron transporting emission (emitting) layers.

The organic electroluminescent layer, i.e., the emissive layer, is a layer within an organic light emitting device which when in operation contains a significant concentration of both electrons and holes and provides sites for exciton formation and light emission. A hole injection layer is a layer in contact with the anode which promotes the injection of holes from the anode into the interior layers of the OLED; and an electron injection layer is a layer in contact with the cathode that promotes the injection of electrons from the cathode into the OLED; an electron transport layer is a layer which facilitates conduction of electrons from the cathode and/or the electron injection layer to a charge recombination site. During operation of an organic light emitting device comprising an electron transport layer, the majority of charge carriers (i.e. holes and electrons) present in the electron transport layer are electrons and light emission can occur through recombination of holes and electrons present in the emissive layer. A hole transporting layer is a layer which when the OLED is in operation facilitates conduction of holes from the anode and/or the hole injection layer to charge recombination sites and which need not be in direct contact with the anode. A hole transporting emission layer is a layer in which when the OLED is in operation facilitates the conduction of holes to charge recombination sites, and in which the majority of charge carriers are holes, and in which emission occurs not only through recombination with residual electrons, but also through the transfer of energy from a charge recombination zone elsewhere in the device. An electron transporting emission layer is a layer in which when the OLED is in operation facilitates the conduction of electrons to charge recombination sites, and in which the majority of charge carriers are electrons, and in which emission occurs not only through recombination with residual holes, but also through the transfer of energy from a charge recombination zone elsewhere in the device.

Materials suitable for use as the anode includes materials having a bulk resistivity of preferred about 1000 ohms per square, as measured by a four-point probe technique. Indium tin oxide (ITO) is frequently used as the anode because it is substantially transparent to light transmission and thus facilitates the escape of light emitted from electro-active organic layer. Other materials, which may be utilized as the anode layer, include tin oxide, indium oxide, zinc oxide, indium zinc oxide, zinc indium tin oxide, antimony oxide, and mixtures thereof.

Materials suitable for use as the cathode include general electrical conductors including, but not limited to metals which can inject negative charge carriers (electrons) into the inner layer(s) of the OLED. Metal oxides such as ITO may also be used. Metals suitable for use as the cathode include K, Li, Na, Cs, Mg, Ca, Sr, Ba, Al, Ag, Au, In, Sn, Zn, Zr, Sc, Y, elements of the lanthanide series, alloys thereof, and mixtures thereof. Suitable alloy materials for use as the cathode layer include Ag—Mg, Al—Li, In—Mg, Al—Ca, and Al—Au alloys. Layered non-alloy structures may also be employed in the cathode, such as a thin layer of a metal such as calcium, or a metal fluoride, such as LiF, covered by a thicker layer of a metal, such as aluminum or silver. In particular, the cathode may be composed of a single metal, and especially of aluminum metal.

The compounds of formula I may be used in electron transport layers in place of, or in addition to traditional materials such as poly(9,9-dioctyl fluorene), tris(8-hydroxyquinolato) aluminum (Alq₃), 2,9-dimethyl-4,7-diphenyl-1,1-phenanthroline, 4,7-diphenyl-1,10-phenanthroline, 2-(4-biphenylyl)-5-(4-t-butylphenyl)-1,3,4-oxadiazole, 3-(4-biphenylyl)-4-phenyl-5-(4-t-butylphenyl)-1,2,4-triazole, 1,3,4-oxadiazole-containing polymers, 1,3,4-triazole-containing polymers, quinoxaline-containing polymers, and cyano-PPV.

Materials suitable for use in hole transporting layers include 1,1-bis((di-4-tolylamino) phenyl)cyclohexane, N,N′-bis(4-methylphenyl)-N,N′-bis(4-ethylphenyl)-(1,1′-(3,3′-dimethyl)biphenyl)-4,4′-diamine, tetrakis-(3-methylphenyl)-N,N,N′,N′-2,5-phenylenediamine, phenyl-4-N,N-diphenylaminostyrene, p-(diethylamino)benzaldehyde diphenylhydrazone, triphenylamine, 1-phenyl-3-(p-(diethylamino)styryl)-5-(p-(diethylamino)phenyl)pyrazoline, 1,2-trans-bis(9H-carbazol-9-yl)cyclobutane, N,N,N′,N′-tetrakis(4-methylphenyl)-(1,1′-biphenyl)-4,4′-diamine, copper phthalocyanine, polyvinylcarbazole, (phenylmethyl)polysilane; poly(3,4-ethylendioxythiophene) (PEDOT), polyaniline, polyvinylcarbazole, triaryldiamine, tetraphenyldiamine, aromatic tertiary amines, hydrazone derivatives, carbazole derivatives, triazole derivatives, imidazole derivatives, oxadiazole derivatives having an amino group, and polythiophenes as disclosed in U.S. Pat. No. 6,023,371.

Materials suitable for use in the light emitting layer include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, or a combination thereof. Materials suitable for use as the phosphorescent dye include, but are not limited to, tris(1-phenylisoquinoline) iridium (III) (red dye), tris(2-phenylpyridine) iridium (green dye) and Iridium (III) bis(2-(4,6-difluorephenyl)pyridinato-N,C2) (blue dye). Commercially available electrofluorescent and electrophosphorescent metal complexes from ADS (American Dyes Source, Inc.) may also be used. ADS green dyes include ADS060GE, ADS061GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

### DEFINITIONS

The term hydrocarbyl as used herein means any organic moiety containing only hydrogen and carbon unless specified otherwise, and may include aromatic, aliphatic, cycloaliphatic and moieties containing two or more of aliphatic, cycloaliphatic and aromatic moieties

As used herein, alkyl is intended to include linear, branched, or cyclic hydrocarbon structures and combinations thereof, including lower alkyl and higher alkyl. Preferred alkyl groups are those of C₂₀ or below. Lower alkyl refers to alkyl groups of from 1 to 6 carbon atoms, preferably from 1 to 4 carbon atoms, and includes methyl, ethyl, n-propyl, isopropyl, and n-, s- and t-butyl. Higher alkyl refers to alkyl groups having seven or more carbon atoms, preferably 7-20 carbon atoms, and includes n-, s- and t-heptyl, octyl, and dodecyl. Cycloalkyl is a subset of alkyl and includes cyclic hydrocarbon groups of from 3 to 8 carbon atoms. Examples of cycloalkyl groups include cyclopropyl, cyclobutyl, cyclopentyl, and norbornyl. Alkenyl and alkynyl refer to alkyl groups wherein two or more hydrogen atoms are replaced by a double or triple bond, respectively.

Aryl and heteroaryl mean a 5- or 6-membered aromatic or heteroaromatic ring containing 0-3 heteroatoms selected from nitrogen, oxygen or sulfur; a bicyclic 9- or 10-membered aromatic or heteroaromatic ring system containing 0-3 heteroatoms selected from nitrogen, oxygen or sulfur; or a tricyclic 13- or 14-membered aromatic or heteroaromatic ring system containing 0-3 heteroatoms selected from nitrogen, oxygen or sulfur. The aromatic 6- to 14-membered carbocyclic rings include, for example, benzene, naphthalene, indane, tetralin, and fluorene; and the 5- to 10-membered aromatic heterocyclic rings include, e.g., imidazole, pyridine, indole, thiophene, benzopyranone, thiazole, furan, benzimidazole, quinoline, isoquinoline, quinoxaline, pyrimidine, pyrazine, tetrazole and pyrazole.

Arylalkyl means an alkyl residue attached to an aryl ring. Examples are benzyl and phenethyl. Heteroarylalkyl means an alkyl residue attached to a heteroaryl ring. Examples include pyridinylmethyl and pyrimidinylethyl. Alkylaryl means an aryl residue having one or more alkyl groups attached thereto. Examples are tolyl and mesityl.

Alkoxy or alkoxyl refers to groups of from 1 to 8 carbon atoms of a straight, branched, cyclic configuration and combinations thereof attached to the parent structure through an oxygen. Examples include methoxy, ethoxy, propoxy, isopropoxy, cyclopropyloxy, and cyclohexyloxy. Lower alkoxy refers to groups containing one to four carbons.

Acyl refers to groups of from 1 to 8 carbon atoms of a straight, branched, cyclic configuration, saturated, unsaturated and aromatic and combinations thereof, attached to the parent structure through a carbonyl functionality. One or more carbons in the acyl residue may be replaced by nitrogen, oxygen or sulfur as long as the point of attachment to the parent remains at the carbonyl. Examples include acetyl, benzoyl, propionyl, isobutyryl, t-butoxycarbonyl, and benzyloxycarbonyl. Lower-acyl refers to groups containing one to four carbons.

Heterocycle means a cycloalkyl or aryl residue in which one to two of the carbons is replaced by a heteroatom such as oxygen, nitrogen or sulfur. Examples of heterocycles that fall within the scope of the invention include pyrrolidine, pyrazole, pyrrole, indole, quinoline, isoquinoline, tetrahydroisoquinoline, benzofuran, benzodioxan, benzodioxole (commonly referred to as methylenedioxyphenyl, when occurring as a substituent), tetrazole, morpholine, thiazole, pyridine, pyridazine, pyrimidine, thiophene, furan, oxazole, oxazoline, isoxazole, dioxane, and tetrahydrofuran.

Substituted refers to residues, including, but not limited to, alkyl, alkylaryl, aryl, arylalkyl, and heteroaryl, wherein up to three H atoms of the residue are replaced with lower alkyl, substituted alkyl, alkenyl, substituted alkenyl, aryl, substituted aryl, haloalkyl, alkoxy, carbonyl, carboxy, carboxalkoxy, carboxamido, acyloxy, amidino, nitro, halo, hydroxy, OCH(COOH)₂, cyano, primary amino, secondary amino, acylamino, alkylthio, sulfoxide, sulfone, phenyl, benzyl, phenoxy, benzyloxy, heteroaryl, or heteroaryloxy.

Haloalkyl refers to an alkyl residue, wherein one or more H atoms are replaced by halogen atoms; the term haloalkyl includes perhaloalkyl. Examples of haloalkyl groups that fall within the scope of the invention include CH₂F, CHF₂, and CF₃.

Many of the compounds described herein may contain one or more asymmetric centers and may thus give rise to enantiomers, diastereomers, and other stereoisomeric forms that may be defined, in terms of absolute stereochemistry, as (R)- or (S)-. The present invention is meant to include all such possible isomers, as well as, their racemic and optically pure forms. Optically active (R)- and (S)-isomers may be prepared using chiral synthons or chiral reagents, or resolved using conventional techniques. When the compounds described herein contain olefinic double bonds or other centers of geometric asymmetry, and unless specified otherwise, it is intended that the compounds include both E and Z geometric isomers. Likewise, all tautomeric forms are also intended to be included.

Oxaalkyl refers to an alkyl residue in which one or more carbons have been replaced by oxygen. It is attached to the parent structure through an alkyl residue. Examples include methoxypropoxy, 3,6,9-trioxadecyl and the like. The term oxaalkyl is intended as it is understood in the art [see Naming and Indexing of Chemical Substances for Chemical Abstracts, published by the American Chemical Society, ¶196, but without the restriction of ¶127(a)], i.e. it refers to compounds in which the oxygen is bonded via a single bond to its adjacent atoms (forming ether bonds); it does not refer to doubly bonded oxygen, as would be found in carbonyl groups. Similarly, thiaalkyl and azaalkyl refer to alkyl residues in which one or more carbons has been replaced by sulfur or nitrogen, respectively. Examples include ethylaminoethyl and methylthiopropyl.

Silyl means an alkyl residue in which one to three of the carbons is replaced by tetravalent silicon and which is attached to the parent structure through a silicon atom. Siloxy is an alkoxy residue in which both of the carbons are replaced by tetravalent silicon that is endcapped with an alkyl residue, aryl residue or a cycloalkyl residue, and which is attached to the parent structure through an oxygen atom.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloromethylphen-1-yl (i.e., 3-CCl₃Ph-), 4-(3-bromoprop-1-yl)phen-1-yl (i.e., 4-BrCH₂CH₂CH₂Ph-), and the like. Further examples of aromatic radicals include 4-allyloxyphen-1-oxy, 4-aminophen-1-yl (i.e., 4-H₂NPh-), 3-aminocarbonylphen-1-yl (i.e., NH₂COPh-), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO—), 4-hydroxymethylphen-1-yl (i.e., 4-HOCH₂Ph-), 4-mercaptomethylphen-1-yl (i.e., 4-HSCH₂Ph-), 4-methylthiophen-1-yl (i.e., 4-CH₃SPh-), 3-methoxyphen-1-yl, 2-methoxycarbonylphen-1-yloxy (e.g. methyl salicyl), 2-nitromethylphen-1-yl (i.e., 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H₁₀C(CF₃)₂C₆H₁₀—), 2-chloromethylcyclohex-1-yl, 3-difluoromethylene cyclohex-1-yl, 4-trichloromethylcyclohex-1-yloxy, 4-bromodichloromethyl cyclohex-1-ylthio, 2-bromoethylcyclopent-1-yl, 2-bromopropylcyclohex-1-yloxy (e.g. CH₃CHBrCH₂C₆H₁₀O—), and the like. Further examples of cycloaliphatic radicals include 4-allyloxycyclohex-1-yl, 4-aminocyclohex-1-yl (i.e., H₂C₆H₁₀—), 4-aminocarbonylcyclopent-1-yl (i.e., NH₂COC₅H₈—), 4-acetyloxycyclohex-1-yl, 2,2-dicyanoisopropylidenebis(cyclo-hex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy (2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic”organic radicals substituted with a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g. —CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e. —CHO), hexyl, hexamethylene, hydroxymethyl (i.e. —CH₂OH), mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e. (CH₃)₃Si—), t-butyldimethylsilyl, 3-trimethyloxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH₂)₉—) is an example of a C₁₀ aliphatic radical.

### EXAMPLES

### Example 1

### Preparation of Oligofluorenes

A general procedure for the preparation of oligofluorenes is exemplified by the synthesis of 392-59: A 200 ml 2-neck flask fitted with a condenser, gas inlet tube and Teflon magnetic stir bar was charged with 9,9-bis-(4-hexyloxyphenyl)-2,7-dibromofluorene, 2.028 g (3.00 mmol), 9,9-dioctyl-2-ethylenedioxyborane, 3.132 g (6.24 mmol), dicyclohexyl-2-(2′,6′-di-methoxyphenyl)phenylphosphine, 0.129 g (0.32 mmol) and toluene, 60 ml. The solution was degassed with argon for 15 minutes and palladium acetate, 0.20 g (0.09 mmol) followed by a degassed solution of tetraethylammonium hydroxide, 2.2 g (15 mmol) in water 22 g. The solution was immersed in a 70° C. oil bath and stirred under a nitrogen blanket for 16 hr. The cooled mixture was diluted with toluene, 50 ml, and water, 25 ml, filtered through a pad of Celite and transferred to a separatory funnel. The aqueous phase was discarded and the organic phase was washed successively with water (2×100 ml) and brine (1×100 ml) then passed through a cone of Drierite. The solution was stirred at room temperature with sodium borohydride ˜25 mg then concentrated under vacuum and the residual oil was chromatographed on 120 g of silica gel eluted with 0-30% ethyl acetate in hexane to afford 2.3 g of a colorless oil: ¹H nmr (CDCl₃) δ 8.0-7.3 (m, 20, fluorene-H), 7.3-6.8 (AB quartet, 8, phenol ether Ar—H), 3.96 (t,4,ArOCH₂), 2.04 (t,8, C9-CH₂), and 1.8-0.6 ppm (m, 60, octyl-H).

### Example 2

### Multiple Layer Structure

The materials of this invention are soluble is common alcohols such as 1-butanol and 1 hexanol. For example, we have found that materials such as JC392-59 and 392-38 may be readily dissolved by 1-hexanol and 1-butanol at a concentration of approximately 10 mg/ml. Once cooled to room temperature, this material can be deposited via spin casting directly from solution onto a poly-fluorene polymer layer that is not dissolved by alcohol solvents. We have found that spin coating a ˜10 mg/ml alcoholic solution at ˜1000 rpm onto a polyfluorene coated glass slide results in an additional film thickness of ˜20 nm, which we assigned to an additional layer of the trimer type material. We have found that it is possible to follow the formation of this bilayer structure both through mechanical and optical thickness measurements of the polymer films on glass. The mechanical measurements are performed by first using a sharp edge to scratch the film, followed by measuring the distance between the top of the film and the glass using a profilometer. (in this case a Tencor P1) The optical measurements are performed by taking advantage of the fact that polyfluorene materials exhibit a peak in their optical absorption at −390 nm and are much less absorbing at −357 nm, where the peak absorption of many of the trimer species of this invention absorb. Thus it is possible to deconvolute the combined by layer absorption into two components, one corresponding to the poly-fluorene the other corresponding to the oligomers of this invention. Since the optical absobance (in OD units) is linearly related to the average thickness, this provides additional support for existence of a bilayer structure.

### Example 3

### OLED Incorporating Multilayer Structure

It is possible to use the advantageous solubility properties of these materials to fabricate an OLED device. To fabricate the device, a layer of PEDOT/PSS (Baytron P VP 8000, a poly(3,4-ethylenedioxythiophene)-poly(styrenesulfonate) obtained as a solution from HC Starck, Inc.) or other hole injecting material having a thickness of about 60 nm can be by spin-coating onto clean, UV-Ozone treated, 2.5 cm×2.5 cm ITO patterned glass substrates. The coated substrates can then be baked on a hot plate in air for 30 minutes at 160° C. A layer of F8-TFB (an octylfluorene-triarylamine copolymer obtained from Sumation, Inc.) hole transporter layer having a thickness of about 10-20 nm can be deposited via spin-coating atop the PEDOT/PSS coated substrates. The F8-TFB-PEDOT/PSS coated substrates can then be baked on a hot plate in argon for 30 minutes at 160° C. A layer comprised of a non alcohol soluble polyfluorene material (obtained from Sumation chemical or American Dye Source) can then be dissolved in a solvent such as xylene and deposited solution atop the F8-TFB layer as an emissive layer. This emissive layer can vary in thickness up to 200 nm, but a thickness of 5 nm-40 nm is preferred. A final layer of layer of the trimer material can be deposited from an alcohol example 1-butanol, 1-hexanol) solution with a preferred thickness in the range of 10 nm-50 nm.

The coated substrates can then be placed into a bell jar evaporator, and the system was pumped until a pressure of about 1×10⁻⁶ torr was obtained. A layer of sodium fluoride about 7 nm thick (as measured via a calibrated quartz crystal microbalance) can then be deposited atop the final layer of the coated substrates by physical vapor deposition. Subsequently, a layer of aluminum metal about 130 nm thick can be deposited atop the sodium fluoride layer by vapor deposition under vacuum to form the cathode component of the OLED.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A solution process for fabricating an optoelectronic device, said process comprising
contacting an electroluminescent layer comprising an alcohol-insoluble electroluminescent polymer with an alcoholic solution of a compound of formula Ia 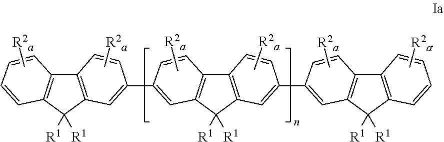
to form an electron transporting layer directly disposed on the electroluminescent layer; and
depositing a metal cathode layer on the electron transporting layer;
wherein
R¹ is, independently at each occurrence, C₁₋₂₀ hydrocarbyl;
at least one of R¹ is R³;
R² is independently at each occurrence hydrogen, C₁₋₂₀ hydrocarbyl, C₁₋₂₀ hydrocarbyloxy, C₁₋₂₀ thioether, C₁₋₂₀ hydrocarbylcarbonyloxy or cyano;
R³ is C₁₋₂₀ hydrocarbyl containing at least one S, N, O or P atom between carbon atoms;
a is independently at each occurrence 0, 1 or 2; and
n is 0 or 1.

2. A solution process according to claim 1, wherein the compound of formula Ia is

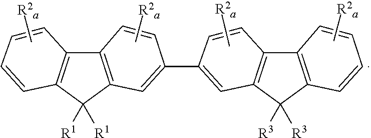

3. A solution process according to claim 1, wherein the compound of formula Ia is

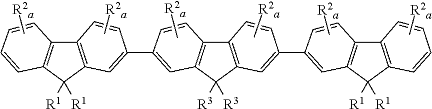

4. A solution process according to claim 1, wherein R³ is C₁₋₂₀ hydrocarbyl containing at least one ether, thioether, ester, thioester, or alkylamino group.

5. A solution process according to claim 1, wherein R³ is 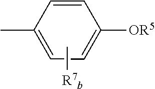
wherein
R⁷ is C₁₋₂₀ hydrocarbyl, C₁₋₂₀ hydrocarbyloxy, C₁₋₂₀ thioether, C₁₋₂₀ hydrocarbylcarbonyloxy or cyano; and
b is 0, 1 or 2.

6. A solution process according to claim 1, wherein the compound of formula Ia is

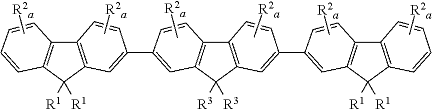

7. A solution process according to claim 1, wherein R¹ is, independently at each occurrence, alkyl or R³.

8. A solution process according to claim 1, wherein R³ is —O(CH₂CH₂O)ₘCH₂CH₂NR₆; and m is 0 or an integer from 0 to about 20.

9. A solution process according to claim 1, wherein R₃ is morpholinyl or pyrrolidinyl.

10. A solution process according to claim 1, wherein R³ is selected from

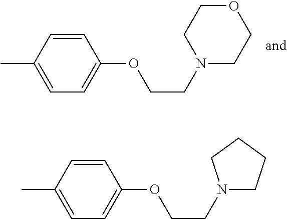 [SMILES: Cc1ccc(OCCN2CCOCC2)cc1 ; Cc1ccc(OCCN2CCCC2)cc1]

11. A solution process according to claim 1, wherein R³ is selected from

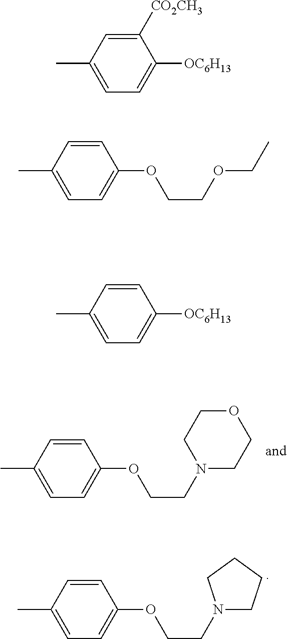

12. A solution process according to claim 1, wherein R¹ is C₈H₁₇ and R³ is selected from

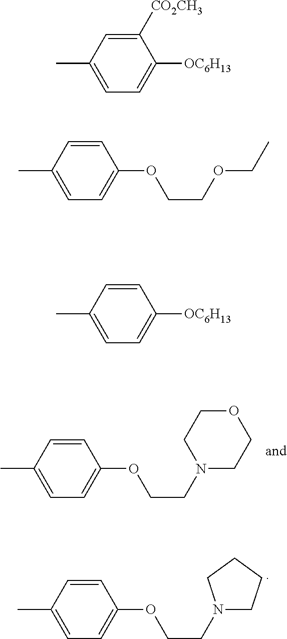

13. A solution process according to claim 1, wherein
R¹ is 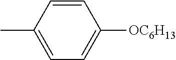
and
R³ is selected from

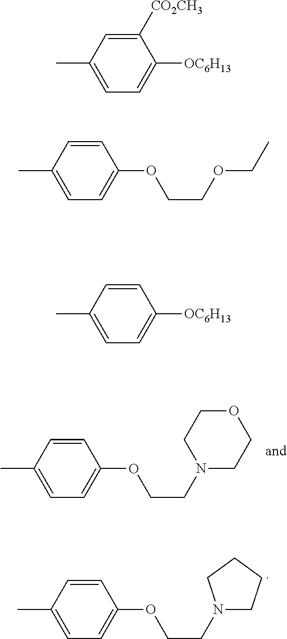

14. A solution process according to claim 1, wherein
R¹ is C₈H₁₇ and R³ is

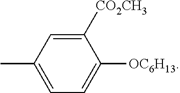

15. A solution process according to claim 1, wherein
R¹ is C₈H₁₇ and R³ is

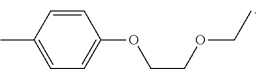

16. An optoelectronic device fabricated by a solution process according to claim 1.
